(19) United States
(12) Patent Application Publication
(10) Pub. No.: US 2011/0253033 A1
(43) Pub. Date: Oct. 20, 2011

(54) CRYSTAL GROWING SYSTEM AND METHOD THEREOF

(75) Inventors: Govindhan Dhanaraj, Merrimack, NH (US); Chandra P. Khattak, Nashua, NH (US); Carl Richard Schwerdtfeger, JR., Wilton, NH (US); Kedar Prasad Gupta, Hollis, NH (US)

(73) Assignee: ADVANCED RENEWABLEENERGY CO. LLC, Nashua, NH (US)

(21) Appl. No.: 13/095,073

(22) Filed: Apr. 27, 2011

Related U.S. Application Data
(63) Continuation-in-part of application No. 12/588,656, filed on Oct. 22, 2009.
(60) Provisional application No. 61/108,213, filed on Oct. 24, 2008.

(51) Int. Cl. C30B 11/00

(52) U.S. Cl. 117/81; 117/223

(57) ABSTRACT

Provided is a system and method for growing crystals. The method includes substantially fully covering a seed crystal in a charge material, using a heat source to melt the charge material, cooling the seed crystal to keep the seed crystal at least partially intact as the charge material melts, allowing at least a portion of the seed crystal to melt into the molten charge material, and continually growing the crystal by reducing the temperature of the heat source, moving the molten charge material and seed crystal from the heat source, and increasing a rate of cooling of the seed crystal.

### CROSS-REFERENCE TO RELATED APPLICATIONS

This application is a continuation-in-part of copending U.S. Nonprovisional patent application Ser. No. 12/588,656, Published Application No. US 2010-0101387, filed Oct. 22, 2009 entitled “CRYSTAL GROWING SYSTEM AND METHOD THEREOF,” the entirety of which is hereby incorporated herein by reference. U.S. Nonprovisional patent application Ser. No. 12/588,656 claims priority under 35 U.S.C. 119 to U.S. Provisional Application No. 61/108,213, filed Oct. 24, 2008, entitled “SYSTEM AND METHOD FOR GROWING CRYSTALS,” the entirety of which is hereby incorporated herein by reference.

### FIELD OF TECHNOLOGY

The present invention relates to a field of growing crystals and more particularly relates to methods and systems for growing large, low defect crystals of, for example, sapphire.

### BACKGROUND

High brightness, low toxicity, low energy use, durability, small form factor, excellent color performance, and continuously decreasing costs, have led to a rapidly growing demand for light emitting diodes (LEDs) in a wide range of applications, such as small displays for mobile devices, flashes for digital cameras, backlighting units for displays used in computer monitors, LED televisions, public display signs, automotive lights, traffic signals, and general and specialty lighting for domestic and commercial premises.

Typically, LEDs are fabricated by growing several types of gallium nitride (GaN) crystalline active layers on a compatible substrate (also referred to as “wafer”). Further, the LEDs thus fabricated may have a mismatch between a crystal lattice of the compatible substrate and the GaN crystalline active layers. The mismatch is preferably small, so that a single crystal layer can be grown on a substrate. The substrate also preferably has high transparency, stability at temperatures up to 1100° C. or more, comparable thermal expansion and heat conduction with the grown GaN crystalline active layers. The physical properties of the preferred substrates (also referred to as “wafers”) are close to those of GaN and other layers, such as aluminum nitride (AIN), GaN, indium gallium nitride (InGaN) and indium gallium aluminum (InGaAl).

Even though there are several other potential substrate materials available, such as silicon carbide (SiC), silicon (Si), zinc oxide (ZnO) and GaN, sapphire (Al₂O₃) is a preferred substrate material for LEDs and other GaN device applications. Sapphire wafers of various diameters, typically two inches or larger in diameter, and various thicknesses, such as 150 or more micrometers (μm) are typically used for the fabrication of LEDs. In sapphire, the (0001) plane orientation has a relatively small mismatch with GaN when compared with other crystallographic orientations.

Currently, sapphire crystals are grown commercially by using one of the following techniques:

1) Czochralski method (Cz);

2) Kyropolous method (Ky);

3) Edge-defined Film Growth (EFG);

4) Vertical Bridgman (VB) method and variants of VB;

5) Horizontal Bridgman (HB) method and variants of HB;

6) Heat Exchanger Method (HEM); and

7) Gradient Freeze (GF) and variants of GF.

However, the above methods have one or more shortcomings, such as: 1) presence of bubbles in the crystal, 2) defects and lattice distortion, 3) crucible design issues, 4) difficulty in measuring actual crystal growth rate, 5) limited size of crystals grown and 6) low wafer yield resulting in excessive cost due to an a-axis growth process. These shortcomings typically produce low yields and high wafer costs. A need exists for improved crystal growth methods, including sapphire crystal growth methods.

### SUMMARY

In one aspect, the present invention is directed to a system for growing crystals from a charge material. The system includes a crucible and at least one heating element adapted to heat the crucible. The system further includes a seed cooling component adapted to receive a coolant fluid to cool a portion of the crucible. The system also includes a gradient control device comprising thermal insulation and adapted to control transport of heat from a vicinity of the bottom of the crucible. The system further includes an insulating element substantially enclosing the crucible, heating element, and gradient control device. The gradient control device and the crucible are independently movable with respect to each other and the heating element.

In another aspect, the present invention is directed to a method for growing a crystal. The method includes substantially fully covering a seed crystal in a charge material, using a heat source to melt the charge material, cooling the seed crystal to keep the seed crystal at least partially intact as the charge material melts, allowing at least a portion of the seed crystal to melt into the molten charge material, and continually growing the crystal by reducing the temperature of the heat source, moving the molten charge material and seed crystal from the heat source, and increasing a rate of cooling of the seed crystal.

In yet another aspect, the present invention is directed to a method for growing a crystal that includes heating a small amount of sapphire in a crucible to above a melting point in a vacuum to form a sapphire vapor, allowing surfaces of the crucible to be coated in the sapphire vapor, quickly cooling the small amount of sapphire and the crucible, removing the small amount of sapphire from the crucible, and subsequently growing a sapphire crystal in the crucible from a seed crystal and sapphire charge material.

In still another aspect, the present invention is directed to a system for growing crystals from a charge material that includes crucible, at least one heating element adapted to heat the crucible, a seed cooling component adapted to receiving a coolant fluid to cool a portion of the crucible, and an insulating element substantially surrounding the crucible and heating element. The insulating element includes at least one radiation shield formed from a refractory metal or alloy.

### BRIEF DESCRIPTION OF THE DRAWINGS

Various preferred embodiments are described herein with reference to the drawings, wherein:

FIG. 1 is a cross-sectional view of a furnace used in growing a single crystal along the c-axis, according to one embodiment;

FIGS. 2 through 4 illustrate a process of formation of a cored c-axis cylindrical ingot from a seed crystal, according to one embodiment;

FIG. 5 is a process flowchart of an exemplary method of certain steps for growing a single crystal about the c-axis using a furnace, such as the one shown in FIG. 1, and thereafter producing wafers using the single crystal, according to one embodiment;

FIG. 6 is a schematic diagram illustrating a controlled heat extraction system (CHES) with the furnace, such as the one shown in FIG. 1, used in growing the single crystal along the c-axis, according to one embodiment;

FIG. 7 is a graphical representation of two different temperature gradients;

FIG. 8 is a table summarizing the state of various parameters during various stages of operation of an embodiment of the present invention; and;

FIGS. 9A and 9B are drawings representing a D-shaped seed crystal and a circular shaped seed crystal, respectively.

The drawings described herein are for illustration purposes only and are not intended to limit the scope of the present disclosure in any way.

### DETAILED DESCRIPTION

A crystal growing system and method thereof is disclosed. In the following detailed description of the embodiments of the invention, reference is made to the accompanying drawings that form a part hereof, and in which are shown, by way of illustration, specific embodiments in which the invention may be practiced. These embodiments are described in sufficient detail to enable those skilled in the art to practice the invention, and it is to be understood that other embodiments may be utilized and that changes may be made without departing from the scope of the present invention. The following detailed description is, therefore, not to be taken in a limiting sense, and the scope of the present invention is defined by the appended claims.

The terms ‘larger solidified single crystal’, ‘larger single crystal’, ‘larger crystal’ and ‘single crystal’ are used interchangeably throughout the document and refer to production scale size crystals grown in accordance with embodiments of the present invention. Also, the terms ‘convex crystal growing surface’ and ‘crystal growing surface’ are used interchangeably throughout the document. Further, the term ‘about an axis’ refers to growing a single crystal approximately −150 to +150 from the axis, where the axis may be one of c-axis, a-axis, m-axis or r-axis. As used herein, the term “isotherm” refers to the solid/liquid interface between a growing crystal and molten material. As used herein, the term “refractory metal” refers to a metal or alloy having a melting temperature greater than 2000° C.

Single crystal sapphire is anisotropic, meaning that its material properties vary significantly depending upon orientation. C-axis orientation is highly desired as a substrate in LED applications because the c-axis orientation has less of a lattice mismatch to GaN films. Conventionally, c-axis sapphire components are obtained from single crystal sapphire grown along the a-axis or m-axis orientations by fabricating the components perpendicular to the axis of growth. For r-axis grown sapphire, the c-axis is oriented about 60 degrees to the axis of growth. Higher yields of c-axis oriented components may be obtained from crystal grown along the c-axis. However, the sapphire growing industry has found that production scale c-axis crystal is more difficult to grow using conventional crystal growth processes, and hence, it has settled for growing a-axis or m-axis crystals and fabricating c-axis cores perpendicular to the growth axis. The present invention provides a system and method of growing a larger solidified single crystal about the c-axis in production. Nevertheless, one can envision that larger single crystals can also be grown about the a-axis, r-axis or m-axis using the system and method of the present invention.

In one aspect, the present invention is directed to a system for growing crystals from a charge material. The system includes a crucible and at least one heating element adapted to heat the crucible. The system further includes a seed cooling component adapted to receive a coolant fluid to a portion of the crucible. The system also includes a gradient control device comprising thermal insulation and adapted to control transport of heat froma vicinity of the bottom of the crucible. The system further includes an insulating element substantially enclosing the crucible, heating element, and gradient control device. The gradient control device and the crucible are independently movable with respect to each other and the heating element.

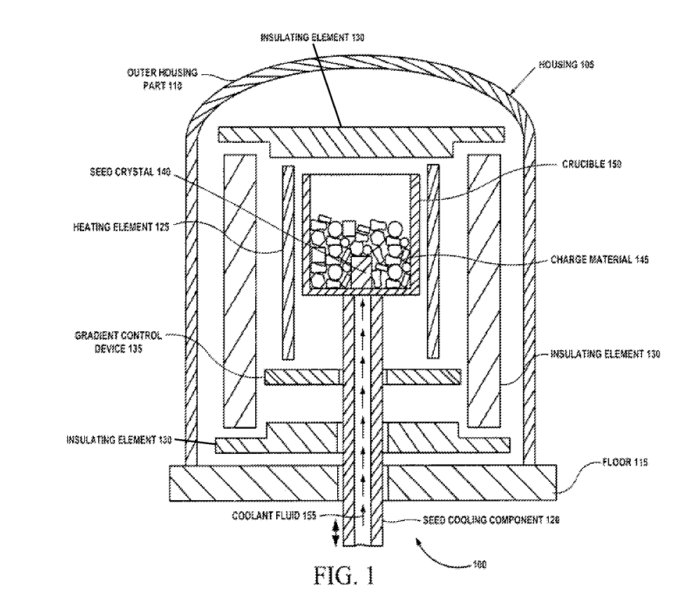

To illustrate, FIG. 1 is a cross-sectional view of a furnace 100 used in one embodiment of the crystal growing system and method of the present invention. In FIG. 1, the furnace 100 may include a housing 105. The housing 105 may include an outer housing part 110 and a floor 115. The outer housing part 110 and the floor 115 together form a chamber, which in certain embodiments may be a double walled, water cooled chamber. The furnace 100 also may include an insulating element 130, a seed cooling component 120, at least one heating element 125, a gradient control device (GCD) 135 and a crucible 150, all of which are enclosed in the outer housing part 110. The elements enclosed in the outer housing part 110 form a “heat zone.” Thus, the heating element 125, crucible 150, gradient control device 135, insulating element 130, and a portion of the seed cooling component 120 are all part of the heat zone. References throughout this application to the heat zone, the melt, the furnace and the chamber may, where context indicates, refer to this interior portion of the chamber.

The insulating element 130 substantially surrounds the seed cooling component 120, the heating element(s) 125 and the crucible 150 and minimizes heat transfer external to the insulating element. The insulating element 130 may be made of material graphite, a high temperature ceramic material, a refractory metal, or an alloy of refractory metals. In some embodiments, the insulating element comprises at least one radiation shield. The insulating element 130 may comprise multiple radiation shields. The radiation shields may be nested in layers around the crucible, heating element, and seed cooling component, and the layers may be spaced apart with spacers formed from the same material as the shields themselves. For high temperature crystal growth applications such as sapphire growth, each radiation shield may be formed from sheets of a refractory metal, such as tungsten or molybdenum, or alloys thereof. In one such embodiment, at least one radiation shield is formed from tungsten. In another embodiment, an innermost radiation shield (i.e., shield closest to the heating element) is formed from tungsten, while an outermost radiation shield (i.e., shield furthest from the heating element) is formed from molybdenum. For example, the insulating element may comprise ten radiation shields nested in layers, where the five innermost radiation shields are formed from tungsten and the five outermost radiation shields are formed from molybdenum. In lower temperature crystal growth applications, the innermost radiation shield or shields may not be formed from tungsten.

The heating element(s) 125 substantially surrounds the seed cooling component 120 and the crucible 150 and is adapted to heat the crucible 150. The heating element may comprise graphite or a refractory metal, such as tantalum, molybdenum, or tungsten, or an alloy of refractory metals. The heating element(s) 125 is adapted to substantially slowly lower the temperature inside the heat zone of the chamber during crystal growth, for example, as slow as 0.02° C./hr

The crucible 150 holds a seed crystal 140 (e.g., D shaped, circular shaped, etc.) and a charge material 145 (e.g., sapphire (Al₂O₃), silicon (Si), calcium fluoride (CaF₂), sodium iodide (NaI), and other halide group salt crystals). The crucible 150 may be made of a refractory metal, such as molybdenum, tungsten, or alloys thereof, or a non-metallic material, such as graphite (C), boron nitride (BN), and the like. In embodiments where the crucible is tungsten, the crucible may be reused in subsequent operations. This presents a cost savings over other crucibles, such as molybdenum crucibles, which, in high temperature crystal growth applications like sapphire growth, are typically one-time use crucibles. In some embodiments, the crucible 150 is capable of holding 0.3 to 450 kilograms of the charge material 145.

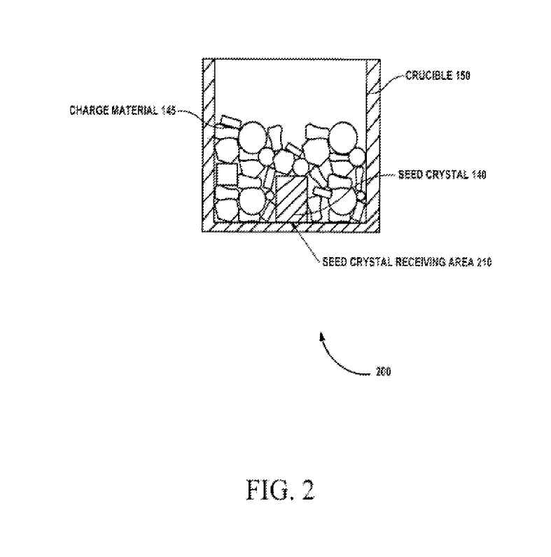

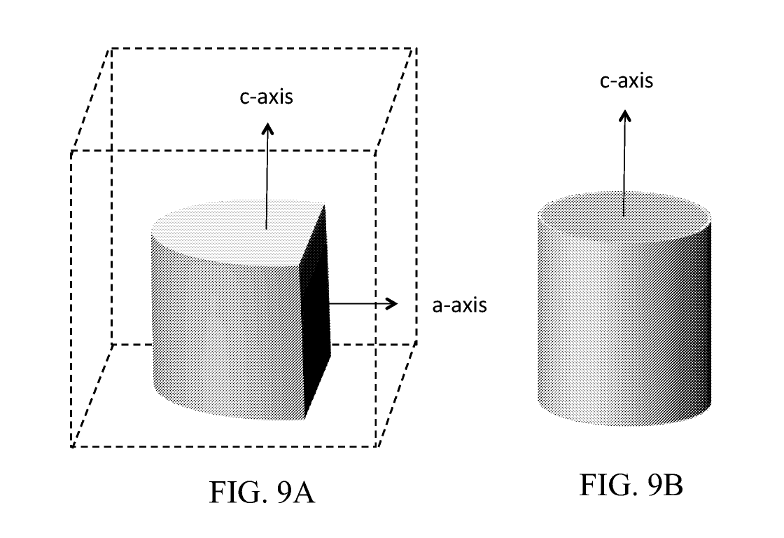

The crucible 150 may include a seed crystal receiving area 210, shown in FIG. 2. The seed crystal receiving area 210 holds the seed crystal 140 in the crucible 150. In the embodiment shown in FIG. 2, the seed crystal receiving area is simply a region at the flat bottom of cylindrical-shaped crucible. However, the seed crystal receiving area may include contours. For example, the seed crystal receiving area may be conical or may include a seed pocket. The seed crystal receiving area may be adapted to fit a seed crystal of particular size and shape in a particular orientation. This facilitates seed crystal placement, and hence crystal growth, along a desired axis and in a desired orientation about the desired axis. The desired orientation may involve alignment of an axis orthogonal to the growth axis with respect to a portion of the crucible. An example of this is illustrated in FIG. 9A, where the walls of a rectangular box-shaped crucible are represented by dotted lines. The D-shaped seed crystal of FIG. 9A is oriented with its c-axis orthogonal to the bottom of the crucible for c-axis growth and its flat side (which is orthogonal to the a-axis) aligned with a side wall of the crucible. In other embodiments, the seed crystal is placed along a desired growth axis, but its orientation about that axis is not limited. For example, a circular shaped c-axis seed crystal, such as the one shown in FIG. 9B, can be oriented in any position within 360° about the c-axis.

In the embodiment shown in FIG. 1, the crucible 150 is supported by the seed cooling component 120 and is movable relative to the heating element(s) 125. The crucible 150 is movable by way of the seed cooling component 120, which can be raised and lowered. The seed cooling component 120 is moved through one or more openings in the floor 115 of the housing 105. As described in further detail below, lowering the crucible via the seed cooling component during the crystal growth phase helps to maintain crystal growth rate and facilitates the growth of a substantially larger crystal.

In some embodiments, the crucible, heating element and at least one of the radiation shields of the insulating element all include tungsten. For example, the crucible, heating element, and an innermost radiation shield of the insulating element (i.e., closest to the heating element) comprise tungsten, while an outermost radiation shield of the insulating element (i.e., furthest from the heating element) comprises molybdenum. In one embodiment, the crucible, heating element, and the insulating element are all entirely formed of tungsten. In other embodiments, the crucible and at least one of the radiation shields of the insulating element comprise tungsten and the heating element comprises carbon. For example, the crucible and an innermost radiation shield of the insulating element comprise tungsten, while an outermost radiation shield of the insulating element comprises molybdenum, and the heating element comprises graphite. In yet other embodiments, the crucible comprises tungsten, while the heating element and insulating element comprise carbon. For example, the heating element may be a graphite heating element and the insulating element may be a graphite felt. In such embodiments where the heating element and/or insulating element comprise carbon, any air present in the atmosphere during crystal growth may react with the heating element and be converted to carbon monoxide. This reaction may be more desirable than an oxidation reaction that would occur in the absence of carbon in the heating element, which can oxidize and damage the heat shields.

As shown in the embodiment of FIG. 1, the seed cooling component 120 may be a hollow component (e.g., made of a refractory metal, such as tungsten (W), molybdenum (Mo), niobium (Nb), lanthanum (La), tantalum (Ta), rhenium (Re) or their alloys) that supports a bottom of the crucible 150. The seed cooling component 120 also receives a coolant fluid 155 (e.g., helium (He), neon (Ne) and hydrogen (H)) to cool the supported portion of the crucible 150 through the hollow portion. The flow rate of the coolant fluid entering the seed cooling component can be controlled to adjust the rate of cooling of the seed crystal.

The gradient control device (GCD) 135 varies the temperature gradient of the melt and/or crystal inside the crucible during different stages of operation. The position of the GCD can be adjusted to control the degree of heat transport near the bottom of the crucible (i.e., the vicinity of the seed crystal), thereby providing the ability to vary the temperature as desired. The GCD comprises thermal insulation. The thermal insulation may comprise a refractory metal, such as tungsten or molybdenum, or may be formed from graphite felt. In some embodiments, the insulation of the GCD comprises radiation shields. Each radiation shield may be formed from a refractory metal, such as tungsten or molybdenum, or alloys thereof. In one embodiment, at least one radiation shield is formed from tungsten. In another embodiment, an innermost radiation shield (i.e., shield closest to the crucible) is formed from tungsten, while an outermost radiation shield (i.e., shield furthest from the crucible) is formed from molybdenum. The radiation shields may be stacked together and spaced apart with spacers formed from the same material as the shields.

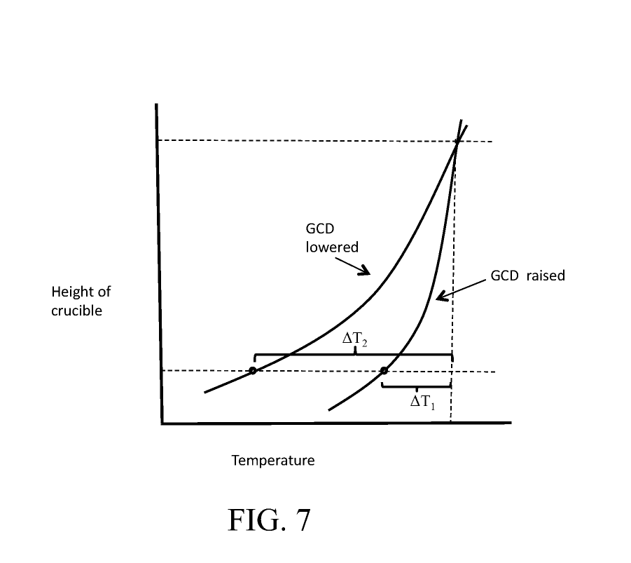

In the embodiment shown in FIG. 1, the GCD is movable relative to the seed cooling component 120, the heating element(s) 125, the insulating element 130 and the crucible 150 over a range of positions. The GCD and the crucible 150 may also move independently with respect to each other. The mobility of the GCD allows it to control the degree of heat transport from the vicinity of the bottom of the crucible, thereby varying the temperature gradient of the contents of the crucible (e.g., growing crystal and melt) as desired. In the embodiment shown in FIG. 1, the GCD is movable along the seed cooling component shaft. In the embodiment shown in FIG. 1, the heat shields of the GCD include openings to allow the GCD to move along the shaft of the seed cooling component. The higher the GCD is positioned on the shaft, the closer it is to the heating element. In a raised position, such as the one shown in FIG. 1, the GCD insulates the vicinity of the bottom of the crucible and seed crystal. As the GCD is moved further from the heating element 125, heat in the vicinity of the bottom of the crucible is allowed to dissipate, and the temperature gradient along the crucible increases. The increase of the temperature gradient effected by the GCD is illustrated in FIG. 7. The figure shows two temperature gradient curves along the height of a crucible in the system of the present invention. The curve on the right represents a temperature gradient along the crucible when the GCD is in a raised position, while the curve on the left represents a temperature gradient when the GCD is in a lowered position. The temperature gradient along the height of the crucible in the raised position is ΔT₁. Placing the GCD in the lower position results in an increased temperature gradient along the crucible, ΔT₂. Different temperature gradients are desirable during the various stages of crystal growth. During melting, a decreased gradient helps to ensure that all the charge is melted and the temperature of the melt is as homogenous as possible. During growth of the crystal, the increased gradient ensures controlled crystal growth from the seed to the top of the melt. During annealing of the crystal, a decreased temperature gradient is typically more desirable. Thus, lowering the GCD during crystal growth and raising the GCD during melting and annealing can achieve a larger single crystal of high quality.

In certain embodiments, the crystal growth system does not include a GCD and/or the crucible is not movable. In such embodiments, the insulating element is formed from a refractory metal. In some such embodiments, the insulating element includes at least one radiation shield. In a specific embodiment, the at least one radiation shield is formed from a refractory metal or alloy.

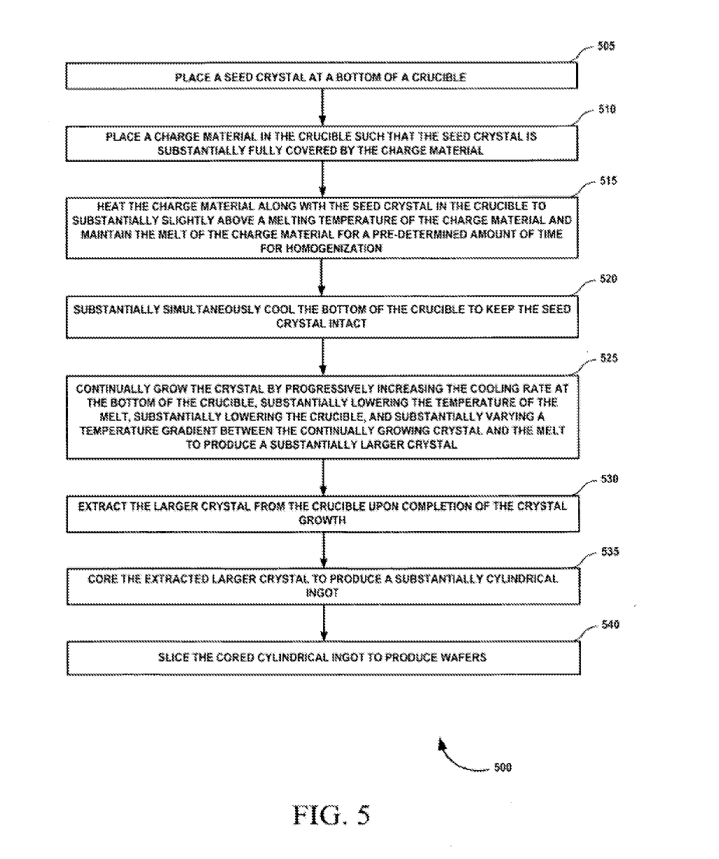

FIG. 5 is a process flowchart 500 of an exemplary method of growing a single crystal about the c-axis using the furnace 100, such as the one shown in FIG. 1, and thereafter producing wafers using the single crystal, according to one embodiment.

In step 505, a seed crystal (e.g., sapphire seed crystal) is placed at a bottom of the crucible 150, for example, in the seed crystal receiving area 210, as shown in FIG. 2 In step 510, a charge material (e.g., a sapphire charge material) is placed in the crucible 150 such that the seed crystal 140 is substantially fully covered by the charge material 14, as shown in FIG. 2. Then, the crucible 150 with the charge material and the seed crystal is loaded into the furnace 100.

In step 515, power to the heating element 125 is supplied to heat the charge material 145 along with the seed crystal 140 in the crucible 150 to substantially slightly above a melting temperature of the charge material 145. For example, in the case of sapphire charge material, the crucible may be heated in the range of about 2040 to 2100° C. The crucible may be raised and/or maintained in a raised position at this time so that it is in closer proximity to the heating element. The GCD can be raised and/or maintained in a raised position to minimize the temperature gradient and ensure a homogenous melt. Once the charge material 145 is completely molten, the molten charge material (also referred to as the “melt” of the charge material) is maintained for a predetermined amount of time for homogenization, typically 1-24 hours.

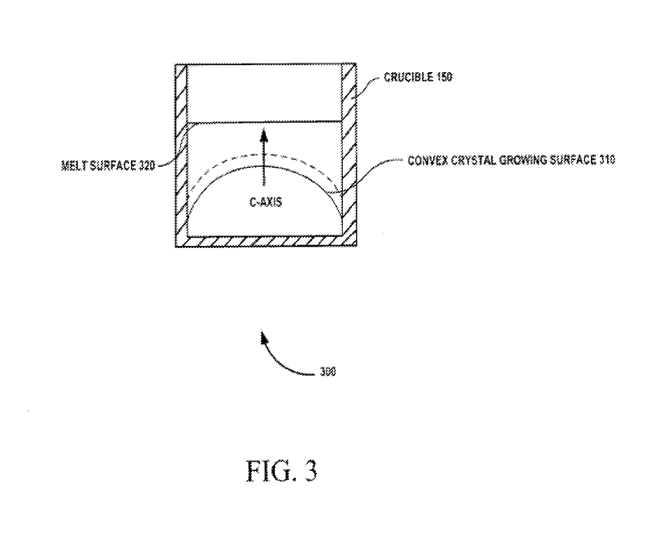

In step 520, the bottom of the crucible 150 and seed crystal 140 may be cooled by flowing the coolant fluid 155 through the seed cooling component 120 simultaneously to the heating of the charge material 145 in step 515. In some embodiments, the bottom of the crucible 150 and seed crystal 140 are cooled using helium when the melt of the charge material is above the melting temperature. For example, helium may be flown through the seed cooling component 120 supporting the bottom of the crucible 150 at a rate approximately in the range of about 10 to 100 lpm. At least a portion of the seed crystal is allowed to melt into the molten charge material, and the bottom of the crucible 150 is cooled such that the seed crystal 140 remains intact and is not melted completely. In the case of a seed crystal oriented along the c-axis, the minimal desired melting may include melting a portion of a top surface (e.g., c-face) of the seed crystal to form a convex crystal growing surface, as shown in FIG. 3. A small portion of the top surface of the seed crystal 140 is melted by increasing the temperature of the melt and/or reducing the flow rate of helium (e.g., from 90 lpm to 80 lpm) through the seed cooling component 201, resulting in a convex (or dome) shaped crystal. The convex crystal growing surface is a true non-habit face (e.g., not the true c-face) having multi-steps made of a-plane and c-plane. The convex crystal growing surface helps stabilize the growth process of the crystal substantially along the c-axis.

In step 525, growth of the crystal is initiated (step 525). In one or more embodiments, as the crystal grows, the cooling rate at the bottom of the crucible 150 is increased progressively by ramping up the flow rate of the coolant fluid 155 through the seed cooling component 120. For example, the flow rate may be increased up to 600 lpm of helium over a period of 24-96 hours. Concurrently, the temperature of the melt may be substantially lowered by substantially slowly lowering the temperature of the heating element(s) 125, for example, at a rate of about 0.02-10° C./hr. As a result, the melt is cooled and a temperature gradient is established between the seed crystal and the melt. The temperature gradient can be substantially increased to ensure continued controlled growth of the crystal and to produce a larger solidified single crystal. This is accomplished by lowering the GCD 135 and/or maintaining the GCD in a lowered position during crystal growth. Lowering the GCD increases the rate of heat transfer from the vicinity of the seed crystal, thereby increasing the temperature gradient along the growing crystal and melt. For example, the GCD may be lowered at a rate of about 0.1-5 mm/hr.

Further, as the crystal grows taller, the distance of the solid-liquid isotherm from the bottom of the crucible increases and the effect of the coolant fluid 155 diminishes, causing the growth rate of the crystal to slow down steadily. To compensate for the reduced growth rate of the crystal, the crucible 150 may be lowered by moving the seed cooling component 120. Lowering the crucible increases the distance between the crucible and the heating element, thereby allowing the melt to cool and maintaining the growth rate of the crystal. In one embodiment, the crucible is lowered at a rate of about 0.1-5 mm/hr.

On completion of the crystal growth, the solidified crystal undergoes an annealing step where the crystal is held at a certain temperature below the melt temperature of the crystal for a certain amount of time before being allowed to cool to room temperature. For example, the heating element is held at a temperature in the range of about 50-200° C. below the melting point of the crystal material for a time period sufficient to achieve temperature homogeneity throughout the crystal. This may be achieved by lowering the temperature of the heating element(s) 125, reducing the flow of the coolant fluid 155 to slow removal of heat from the bottom of the crucible 150, and moving the GCD 135 to a favorable position to reduce the temperature gradient. For example, the temperature of the heating element can be lowered at a rate of about 0.02 to 50° C./hr and the GCD can be raised during the annealing stage in order to reduce the temperature gradient, thereby bringing the solidified crystal to a more uniform temperature. In addition, the crucible can be raised or maintained in the crystal growth position during the annealing stage to ensure annealing of the solidified single crystal prior to cooling.

After annealing, the temperature of the furnace 100 is gradually reduced to gradually and uniformly cool the annealed crystal to room temperature. The GCD and crucible both may be maintained in the anneal position or may be lowered at this time. The rate of coolant fluid to the seed cooling component may be further reduced, or the anneal rate may be maintained. Further, inert gas pressure inside the furnace 100 can be increased before the larger solidified single crystal is extracted from the furnace 100.

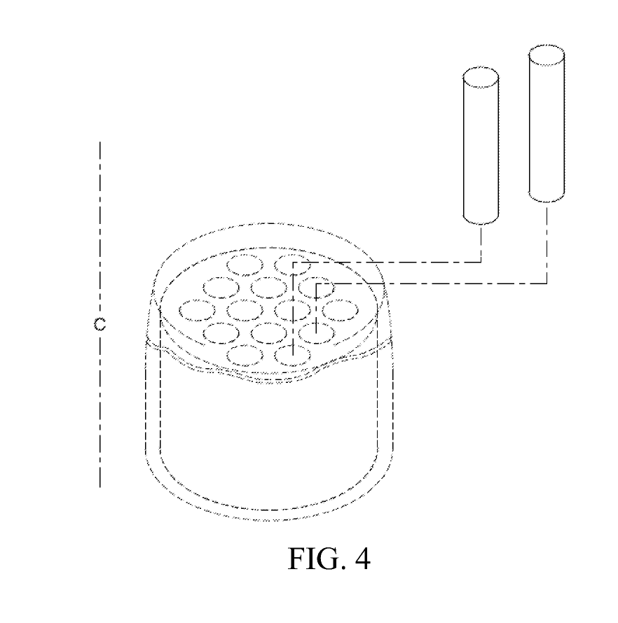

In step 530, the larger crystal is extracted from the crucible 150 upon completion of the crystal growth. In step 535, the extracted larger crystal is cored to produce a substantially cylindrical ingot. In one embodiment, the cylindrical ingot is produced by coring substantially perpendicular to the top surface of the extracted larger crystal, as shown in FIG. 4. In step 540, the cored cylindrical ingot is sliced to produce wafers. It should be noted that while FIG. 5 depicts steps in an exemplary method, in alternative embodiments that would be understood by one of ordinary skill in the art, certain steps may be altered or omitted, the order of steps may be adjusted, or additional steps may be included. Such additional steps may include evacuating the chamber, backfilling the chamber with a gas, such as argon, and the like.

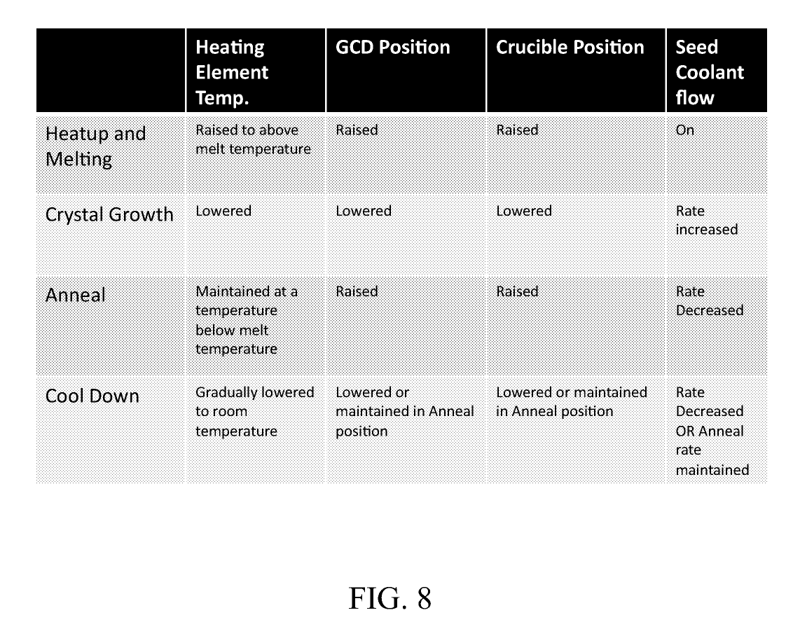

As described above, the temperature of the heating element 125, the position of the crucible 150, the flow rate of the cooling fluid in the seed cooling component, and the position of the GCD 135 can be manipulated during the various stages of the process to optimize the production of a solid monocrystal. An example of this is illustrated in FIG. 8, which summarizes the state of these parameters during various stages in one embodiment of the present invention.

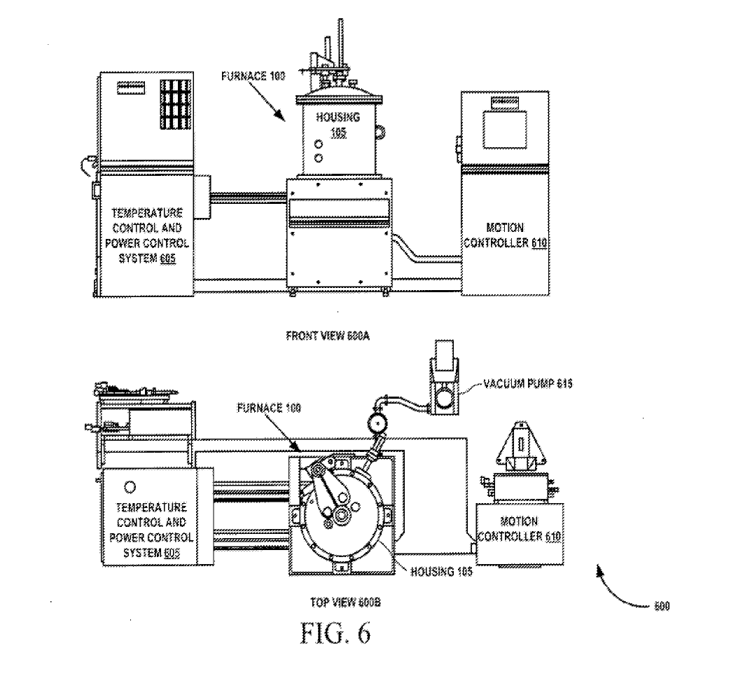

FIG. 6 is a schematic diagram illustrating a controlled heat extraction system (CHES) 600 with the furnace 100, such as those shown in FIG. 1, used in growing the single crystal along the c-axis, according to one embodiment. In particular, FIG. 6 illustrates a front view 600A and a top view 600B of the CHES 600 used in growing the single crystal. The front view 600A and the top view 600B together illustrate various components of the CHES 600. As illustrated, the CHES 600 may include the furnace 100 with the housing 105, a temperature control and power control system 605, a motion controller 610 and a vacuum pump 615. As mentioned above, the furnace 100 for growing crystals may include the seed cooling component 120 along with the crucible 150, the heating element(s) 125, the insulating element 130 and the GCD 135 enclosed in the housing 105. The temperature control and power control system 605 is configured to precisely control the temperature of the heating element(s) 125 within an average at least ranging from −0.2° C. to +0.2° C., even at temperatures in excess of 2000° C. For example, the temperature control and power control system 605 controls the temperature of the heating element(s) 125 such that the charge material 145 is heated above the melting temperature of the charge material 145. The temperature control and power control system 605 can also control the temperature of the heating element(s) 125 such that the temperature of the heating element(s) 125 is lowered, for example, at a rate of about 0.02 to 5° C./hr during the growth stage.

The motion controller 610 is configured to control the movement of the seed cooling component 120 along with the crucible 150. For example, the motion controller 610 lowers the seed cooling component 120 along with the crucible 150 to maintain the growth rate of the crystal. The motion controller 610 is also configured to control the position of the GCD 135. For example, the motion controller 610 moves the GCD 135 over a range of positions to maintain the growth rate of the crystal. It can be noted that, the motion controller 610 is configured to independently control the movement of the seed cooling component 120 and the position of the GCD 135.

The vacuum pump 615 creates and maintains a vacuum (e.g., partial vacuum or full vacuum) inside the housing 105 and gas flow at a controlled rate can be introduced into the chamber such that the crystal can be grown in a controlled atmosphere. The pressure can be varied as desired during each stage of the crystal growth process. In one example, the chamber is evacuated to a full vacuum (e.g., about 0.1 millitorr) and the vacuum is maintained during the heating stage. As the temperature of the charge material approaches the melting point, for example, about 25-200° C. below the melting point, more preferably about 100° C. below the melting point, an inert gas such as argon is introduced to establish a sub-atmospheric (i.e., less than 1 atm) pressure in the chamber. This pressure is maintained during melting of the charge and growth of the crystal. During the annealing stage, where the temperature is reduced, the pressure may be maintained, reduced to a lower pressure, or reduced to a full vacuum.

In some embodiments, an argon atmosphere rather than a vacuum is provided for crystal growth. For example, when a graphite heating element and/or graphite insulating element is used, sapphire crystal growth can be carried out under a flowing argon blanket to minimize vaporization of sapphire and possible reactions between sapphire vapor and the carbon heating element. In addition, crucibles and/or insulating elements made of tungsten and/or molybdenum may have a thin oxide layer, which can peel off at high temperatures and contaminate the sapphire. In such cases, argon and hydrogen gas may be used to conduct a “bake-out” cycle. Specifically, a mixture of argon with about 10% or less of hydrogen by volume can be heated with the components to remove the oxide layer on the refractory metals.

When a furnace such as the one shown in FIG. 1 is first placed into operation, the product of the initial run may not be of sufficient quality, because the components of the furnace are not conditioned. The crystal growth process can occur over the course of days, so this problem presents a significant expense of time and resources. A conditioning run can be carried out where only a small amount (about 1-10 kg) of sapphire is placed in the crucible. The furnace is heated above the melting point of sapphire for a period as short as 8 hours under a vacuum such that sapphire vapors coat the components (e.g. crucible and insulating element) and then quickly cooled by ramping down power to the heating element over a period of about 2-4 hours. Even though the power input to the furnace is reduced to zero, the furnace interior may still be hot (depending on the parameters used) and therefore should be opened after the interior temperature is also reduced, for example, after about 8 additional hours. The conditioning run is low cost, quick, and ensures that subsequent runs produce crystals of acceptable quality.

Controlled Heat Extraction System (CHES) is a directional solidification process, which, in the various embodiments disclosed herein, may be used for growth of crystals, such as sapphire (single crystal form of aluminum oxide) boules. Sapphire's attractive mechanical, thermal and optical properties have been used for high performance, high temperature, robust, abrasion resistant, large windows for civilian and military applications. Recently sapphire substrates have become the substrate choice for light emitting diodes (LED), which has attractive potential for widespread use in low cost, reliable, durable, high performance lighting applications. While this disclosure is primarily directed towards sapphire and LED applications using CHES approach, to one skilled in the art, certain elements of it can be applied to other materials, different applications and for other processes.

Although the present embodiments have been described with reference to specific example embodiments, it will be evident that various modifications and changes may be made to these embodiments without departing from the broader spirit and scope of the various embodiments. In addition, it will be appreciated that the various operations, processes, and methods disclosed herein may be may be performed in any order. Accordingly, the specification and drawings are to be regarded in an illustrative rather than a restrictive sense.

What is claimed is:

1. A system for growing crystals from a charge material, comprising:
a crucible;
at least one heating element adapted to heat the crucible;
a seed cooling component adapted to receive a coolant fluid to cool a portion of the crucible;
a gradient control device comprising thermal insulation and adapted to control transport of heat from a vicinity of a bottom of the crucible; and
an insulating element substantially surrounding the crucible, heating element, and gradient control device,
wherein the gradient control device and the crucible are independently movable with respect to each other and the at least one heating element.

2. The system of claim 1, wherein the thermal insulation of the gradient control device comprises multiple radiation shields.

3. The system of claim 2, wherein at least one of the multiple radiation shields of the gradient control device comprises tungsten.

4. The system of claim 4, wherein an innermost radiation shield of the gradient control device comprises tungsten and an outermost radiation shield of the gradient control device comprises molybdenum.

5. The system of claim 1, wherein the crucible and heating element comprise tungsten, and the insulating element comprises multiple radiation shields, wherein at least one of the radiation shields of the insulating element comprises tungsten.

6. The system of claim 5, wherein an innermost radiation shield of the insulating element comprises tungsten and an outermost radiation shield of the insulating element comprises molybdenum.

7. The system of claim 1, wherein the crucible comprises tungsten, the heating element comprises carbon, and the insulating element comprises multiple radiation shields, wherein at least one of the radiation shields of the insulating element comprises tungsten.

8. The system of claim 1, further wherein the crucible comprises a seed crystal receiving area adapted to accept a seed crystal along a desired axis and in a desired orientation along the desired axis.

9. The system of claim 1, wherein the crucible is reusable.

10. The system of claim 1, wherein the crucible comprises tungsten, and the heating element and insulating element comprise carbon.

11. A method for growing a crystal, comprising:
substantially fully covering a seed crystal in a charge material;
using a heat source to melt the charge material;
cooling the seed crystal to keep the seed crystal at least partially intact as the charge material melts;
allowing at least a portion of the seed crystal to melt into the molten charge material; and
continually growing the crystal by reducing the temperature of the heat source, moving the molten charge material and seed crystal from the heat source, and increasing a rate of cooling of the seed crystal.

12. The method of claim 11, further including the step of increasing a temperature gradient along the growing crystal and the molten charge material by increasing the rate of heat transport from a vicinity of the seed crystal.

13. The method of claim 11, wherein the charge material is under vacuum and an inert gas is introduced at a sub-atmospheric pressure when the charge material reaches a temperature of about 25-200° C. below its melting point.

14. A method for growing a crystal, comprising:
heating a small amount of sapphire in a crucible to above a melting point in a vacuum to form a sapphire vapor;
allowing surfaces of the crucible to be coated in the sapphire vapor;
quickly cooling the small amount of sapphire;
removing the small amount of sapphire from the crucible; and
subsequently growing a sapphire crystal in the crucible from a seed crystal and sapphire charge material.

15. A system for growing crystals from a charge material, comprising:
a crucible;
at least one heating element adapted to heat the crucible;
a seed cooling component adapted to receive a coolant fluid to cool a portion of the crucible; and
an insulating element substantially surrounding the crucible and heating element,
wherein the insulating element comprises at least one radiation shield formed from a refractory metal or alloy.
